(19) United States
(12) Patent Application Publication
(10) Pub. No.: US 2010/0014234 A1
(43) Pub. Date: Jan. 21, 2010

(54) Light-Emitting Pixel Array Package And Method of Manufacturing The Same

(75) Inventor: Patrick O. Weber, Santa Clara, CA (US)

Correspondence Address: Nixon Peabody LLP, P.O. Box 60610, Palo Alto, CA, 94306, US

(73) Assignee: HESTIA TECHNOLOGIES, INC., Santa Clara, CA (US)

(21) Appl. No.: 12/174,518

(22) Filed: Jul. 16, 2008

(51) Int. Cl. H05K 7/18; B29D 11/00; H05K 3/20

(52) U.S. Cl. 361/679.06; 264/1.7; 29/831

(57) ABSTRACT

A method of manufacturing a display monitor, the method comprising: molding a pixel array frame having a plurality of pixel cavities and at least one pixel wall positioned adjacent to at least two pixel cavities, at least one of the pixel cavities having a light pit therein; molding a light diffusing material in the pixel cavities, wherein the light diffusing material does not enter the light pit; selecting a substrate having a top surface and a bottom surface, the substrate having a light source, such as a LED, on the top surface; coupling the bottom surface of the substrate to a printed circuit board configured to controllably operate the light source, wherein the light source is received within the light pit; and coupling the molded pixel array frame to the substrate.

### TECHNICAL FIELD

The present disclosure relates generally to a light-emitting pixel array package and a method of manufacturing the same.

### BACKGROUND

Light emitting diodes (LED) are becoming ever so popular since manufacturers have significantly increased the radiant flux or brightness to allow LEDs to be used in many other applications. As the cost of energy increases, LEDs are replacing existing florescent, halogen and tungsten filament light emitting products.

Some of the applications which utilize LEDs are medium and large sized displays used in casinos, hotels, clubs, sports gaming, convention centers, concerts, movie theaters, malls, airports, etc. The physical display size is measured in feet and not inches. The displays are produced by using red, green and blue LEDs that are then put into one pixel housing to make a pixel, whereby several pixel housings are positioned adjacent to one another to produce a pixel array. Several pixel arrays are positioned next to each other to make the display. Common display resolutions are 480×640 (or 307,200 pixels) or 768×1024 (786,432 pixels). Each color in each pixel is controlled by electronics such that it can produce color spectrum of over 16 million colors.

These displays are commonly rated by two parameters which are “viewing distance” and “viewing angle”. The viewing distance is how far or how close to the display a viewer can be and still “resolve” an image. Typically, the larger the pixel, the farther the viewer has to be from the display to resolve an image on the display. The viewing angle is how far from the center of the display a viewer can be without experiencing degradation of the brightness of the image on the display. A larger viewing angle means a larger audience can view the image from an angle with respect to the center of the display. Larger view angles can also translate into closer view for anybody off the center of the display. Viewing angles typically range from 100 to 170 degrees from the center.

Another variable that controls image quality is the “gap” between the pixels. When viewing a display close up one can see “black gaps” between the pixels. Smaller the gap, the closer one can get to the display to resolve an image. Smaller gaps improve the image definitions as well.

What is needed is a pixel array package which reduces the gap between pixels as well as a method of manufacturing the pixel array package to overcome deficiencies in current pixel array packages as will be discussed herein.

### OVERVIEW

In an aspect, a method of manufacturing a display monitor. The method comprises molding a pixel array frame having a plurality of pixel cavities and at least one pixel wall that is positioned adjacent to at least two pixel cavities. At least one of the pixel cavities has a light pit therein. The method comprises molding a light diffusing material in the pixel cavities, wherein the light diffusing material does not enter the light pit. The method comprises selecting a substrate having a top surface and a bottom surface, the substrate having a light source such as a LED, on the top surface. The method comprises coupling the bottom surface of the substrate to a printed circuit board configured to controllably operate the light source, wherein the light source is received within the light pit. The method comprises coupling the molded pixel array frame to the substrate.

In an aspect, a method of manufacturing a display monitor. The method comprises molding a pixel array frame having a top surface and a bottom surface. The pixel array frame has a plurality of pixel cavities and at least one pixel wall positioned adjacent to at least two pixel cavities, whereby at least one of the pixel cavities has a light pit proximal to the bottom surface. The method comprises molding a light diffusing material in the pixel cavities, wherein the light diffusing material does not enter the light pit.

In an aspect, a method of manufacturing a display monitor. The method comprises molding a pixel array frame having a plurality of pixel cavities and at least one pixel wall positioned adjacent to at least two pixel cavities. The method comprises at least one of the pixel cavities having a light pit therein. The method comprises molding a light diffusing material in the pixel cavities, wherein the light diffusing material does not enter the light pit. The method comprises selecting a substrate having a top surface and a bottom surface, the substrate having a light source on the top surface. The method comprises coupling the bottom surface of the substrate to a printed circuit board configured to controllably operate the light source, wherein the light source is received within the light pit. The method comprises coupling the molded pixel array frame to the substrate.

In an embodiment, the method comprises selecting a substrate having a top surface and a bottom surface, the substrate having a light source on the top surface. In an embodiment, the method comprises coupling the bottom surface of the substrate to a printed circuit board configured to controllably operate the light source. The method comprises coupling the molded pixel array frame to the substrate wherein the light source is received within the light pit. In an embodiment, the pixel frame array is made of a polycarbonate material. In an embodiment, the method comprises coupling a plurality of conductive leads adapted to the bottom surface of the substrate in a substantially circular pattern with respect to a center point. In an embodiment, the method comprises forming an alignment hole in the bottom surface of the pixel array frame, wherein the alignment hole is configured to align the pixel array frame to a substrate having a light source thereon. In an embodiment, the method comprises forming an alignment hole in the bottom surface of the pixel array frame, wherein the alignment hole is configured to align the pixel array frame to the top surface of the substrate. In an embodiment, the bottom surface of the substrate has an alignment hole formed therein, wherein the alignment hole is configured to receive a alignment member of the printed circuit board therein to align the substrate to the printed circuit board.

In an aspect, a pixel array package comprises a pixel array frame having a plurality of pixel cavities and at least one pixel wall positioned adjacent to at least two pixel cavities. At least one of the pixel cavities has a light pit therein. The molded pixel array frame has a light diffusing material in the pixel cavities; a substrate having a top surface and a bottom surface. The substrate has a light source on the top surface, wherein the top surface of the substrate is coupled to a bottom surface of the pixel array frame, wherein the light source fits within the light pit. A plurality of conductive leads are adapted to couple the substrate to a printed circuit board, and the conductive leads coupled to the bottom surface of the substrate are in a substantially circular pattern with respect to a center point.

In an embodiment, an alignment hole in the bottom surface of the substrate, wherein the alignment hole is adapted to receive a corresponding alignment member from a printed circuit board when the substrate is coupled to the printed circuit board. In an embodiment, the pixel walls are filled with a gas and/or a reflective material. In an embodiment, a reflective element on an interior surface of the pixel cavities proximal to the light pit, wherein the reflective element extends upward a desired distance from the bottom surface of the pixel array frame. In an embodiment, an alignment hole in the bottom surface of the pixel array frame, wherein the alignment hole is configured to align the pixel array frame to the top surface of the substrate. In an embodiment, a light diffusing layer material on the top surface of the pixel array frame.

In an aspect, a method of manufacturing a pixel array package comprises molding a pixel array frame having a top surface and a bottom surface separated by a first height dimension. The pixel array frame has a plurality of pixel cavities having of a light diffusing material formed therein and separated by pixel walls having a space devoid of material, wherein each pixel cavity includes a light pit proximal to the bottom surface, the light pit being free of the light diffusing material, each pixel cavity separated by a bridged area of light diffusing material proximal to the top surface and positioned above the pixel walls wherein the bridged area of light diffusing material has a second height dimension less than the first height dimension. The method comprises removing a segment of the light diffusing material at the bridged area, wherein the removed segment extends from the top surface down a third height dimension toward the bottom surface. The removed segment is configured to prevent light from a first pixel cavity from diffusing into an adjacent second pixel cavity.

In an embodiment, the method comprises applying a reflective material within the space of the pixel walls. In an embodiment, the segment has a width dimension substantially equal to a width dimension of the pixel wall. In an embodiment, the third dimension is less than the second dimension or substantially equal to the second dimension. In an embodiment, the method comprises applying a reflective element on an interior surface of the pixel cavity proximal to the light pit, wherein the reflective element extends upward from the bottom surface of the pixel array frame a desired distance. In an embodiment, the method comprises applying a light diffusing layer material on the top surface of the pixel array frame.

### BRIEF DESCRIPTION OF THE DRAWINGS

The accompanying drawings, which are incorporated into and constitute a part of this specification, illustrate one or more examples of embodiments and, together with the description of example embodiments, serve to explain the principles and implementations of the embodiments.

In the drawings:

FIGS. 1A-1F illustrate various views of an existing light emitting pixel array.

FIG. 2A illustrates a schematic of a pixel array package mounted to a motherboard in accordance with an embodiment.

FIG. 2B illustrates a bottom view of a pixel array package in accordance with an embodiment.

FIG. 2C illustrates a schematic of a pixel array package mounted to a motherboard undergoing warping in accordance with an embodiment.

FIG. 3 illustrates a bottom view of a grid-plan pixel array package in accordance with an embodiment.

FIGS. 4A-4F illustrate process steps of manufacturing a pixel array package in accordance with an embodiment.

FIG. 5A-5B illustrate a diagram of segmenting a mold of produced pixel array frames into a plurality of individual pixel array frames.

FIG. 6A illustrates a perspective view of a pixel array frame in accordance with an embodiment.

FIGS. 6B-6D illustrate process steps of manufacturing a pixel array frame in accordance with an embodiment.

FIG. 7 illustrates a schematic of a pixel array frame in accordance with an embodiment.

FIG. 8 illustrates a schematic of a pixel array frame in accordance with an embodiment.

FIGS. 9A-9D illustrate process steps of manufacturing a pixel array package in accordance with an embodiment.

### DESCRIPTION OF EXAMPLE EMBODIMENTS

Example embodiments are described herein in the context of a light-emitting pixel array package and method of manufacturing the same. Those of ordinary skill in the art will realize that the following description is illustrative only and is not intended to be in any way limiting. Other embodiments will readily suggest themselves to such skilled persons having the benefit of this disclosure. Reference will now be made in detail to implementations of the example embodiments as illustrated in the accompanying drawings. The same reference indicators will be used throughout the drawings and the following description to refer to the same or like items.

In the interest of clarity, not all of the routine features of the implementations described herein are shown and described. It will, of course, be appreciated that in the development of any such actual implementation, numerous implementation-specific decisions must be made in order to achieve the developer's specific goals, such as compliance with application- and business-related constraints, and that these specific goals will vary from one implementation to another and from one developer to another. Moreover, it will be appreciated that such a development effort might be complex and time-consuming, but would nevertheless be a routine undertaking of engineering for those of ordinary skill in the art having the benefit of this disclosure.

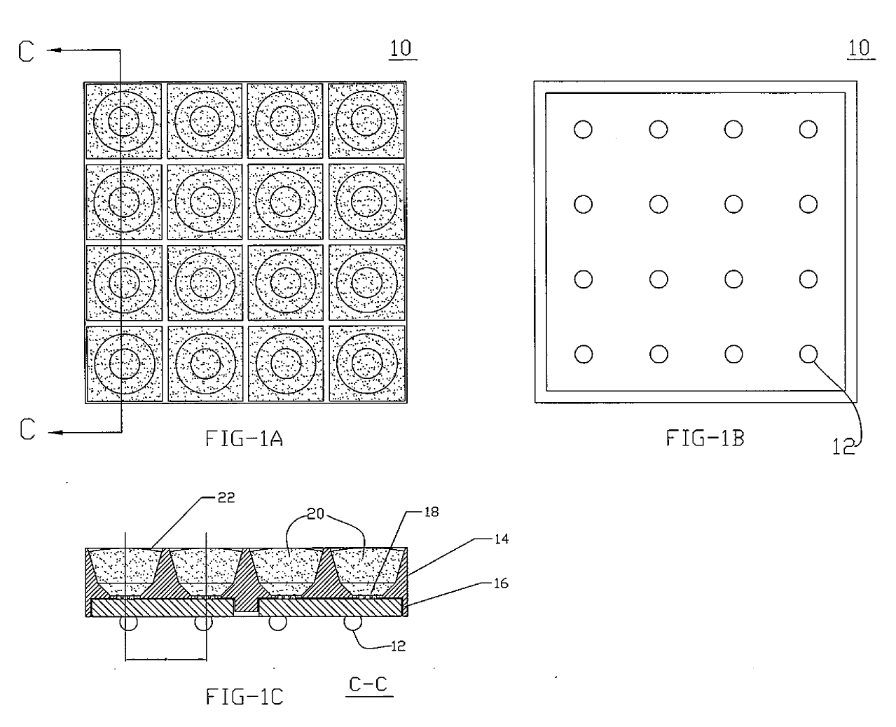

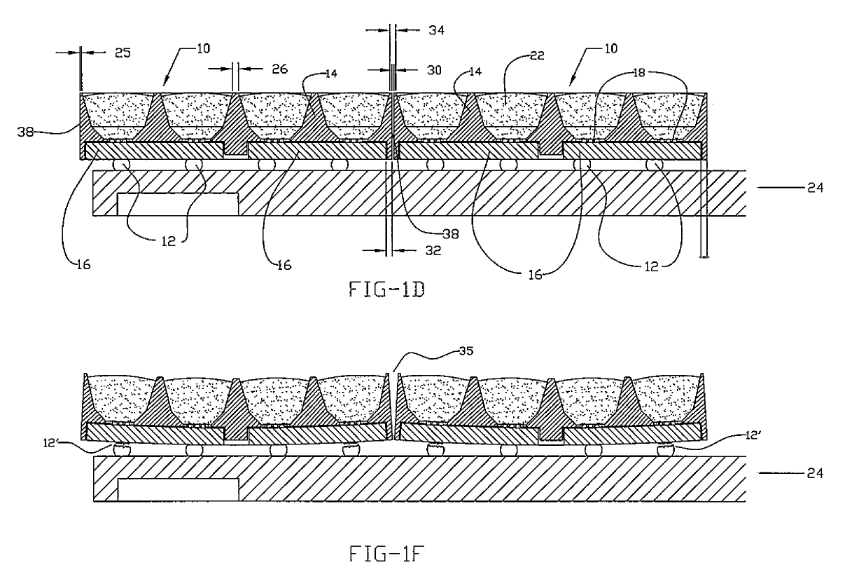

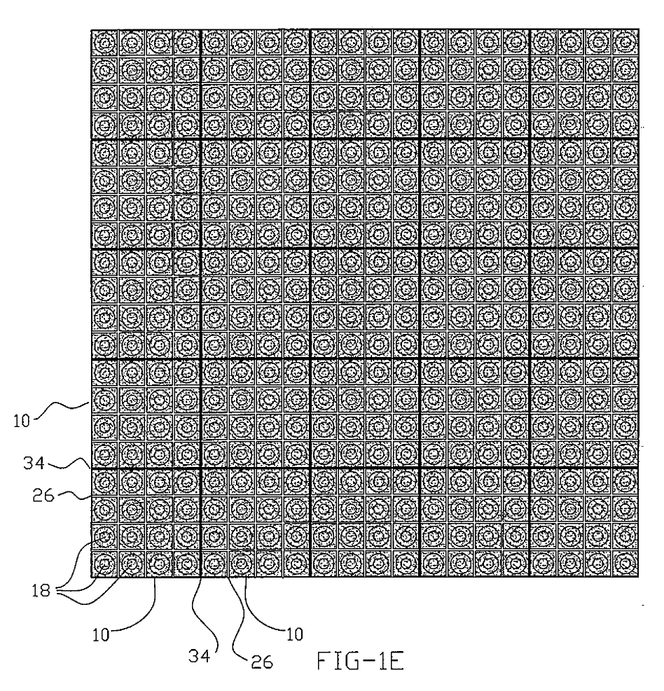

FIGS. 1A-1E illustrate various views of an existing light emitting pixel array. In particular, FIG. 1A illustrates a top view of a 4×4 or 16 pixel array. FIG. 1B illustrates a bottom view of the pixel array which shows a plurality of conductive leads 12, such as solder balls, in a square like pattern. FIG. 1C illustrates a cross-sectional view of the pixel array in FIG. 1A along line C-C.

In particular, as shown in FIG. 1C, the array 10 includes a reflector frame 14 which is attached to a substrate 16 using an epoxy adhesive to produce a pixel array package. The reflector frame 14 is made from conventional thermoplastic that is injection molded, such as white polycarbonate which produces a diffused reflection from the light sources 18. Reflection of light may be specular in that the light bounces off the surface in a mirror-like manner in which the reflected light retains the images of the incident light. Reflection of light may alternatively diffuse off a surface in which the diffused light does not retain the image, but only the energy, depending on the nature of the interface. The substrate 16 is an organic base laminate material with circuit pattern etched on two or more layers, whereby the layers are electrically and mechanically connected using conventional means. The light emitting diodes (LEDs) 18 are attached to the substrate 16 using silver epoxy, whereby wire bonds from the LEDs 18 to the substrate pad provide electrical connection to the LEDs 18.

In manufacturing the reflector frame 14, a clear, cured encapsulation epoxy with diffusant 22 mixed therein is dispensed into the pixel cavities 20 to cover and protect the LEDs 18 and wire bonds from mechanical and environmental damage. Common diffusants are aluminum oxide or calcium carbonate which are grounded to a powder and used to scatter light to maximize the viewing angle of light emitted from the LEDs through the top surface of the encapsulation epoxy 22. A series of ball grid array solder balls 12 are mounted to a bottom surface of the substrate 16, as shown in FIGS. 1B and 1C which electrically couple the assembly to a motherboard 24 (see FIG. 1D).

The total number of pixel arrays required to make a display monitor of 768×1024 resolution is a 192×256 pixel array having a total of 49,152 pixels arrays. The size of the monitor is a function of the distance between center of one pixel to the center of next pixel or the pixel pitch, shown has distance P in FIG. 1C. For example, if the pixel pitch P is 0.200 inches, the size of the display monitor having a 768×1024 pixel resolution would be 12.8 feet×17.1 feet for a monitor. The pixel frame package is mounted and electrically connected to a motherboard 24 via the plurality of leads 12 as shown in FIG. 1D. A plurality of motherboards, each having a predetermined number of pixel frame packages, may be attached to a display frame to create the finished display monitor. FIG. 1E illustrates a top view of a 5×5 pixel frame package assembly, whereby each pixel frame package 10 has a 4×4 pixel array light grid. As shown in FIG. 1E between each 4×4 pixel array is a pixel gap 34, whereby a pixel gap 34 is present on at least two sides of any square pixel package.

The pixel array made using the above described method has number of technical disadvantages. One disadvantage is the mismatch between thermal coefficient expansion (TCE) rates between the encapsulation material 22 and the reflector frame 14, as shown in FIG. 1D. As stated above, the reflector frame 14 is made out of plastic which has a TCE rate in the range from 50-70 PPM per deg C. In addition, the cured encapsulation epoxy 22 has a TCE of approximately 50 PPM per deg C. In comparison, a substrate 16 made of a laminated sheets of woven fiberglass has a TCE in the range of 14-16 PPM per deg C. Thus, warping of the pixel array packaging occurs after the reflector frame 14, filled with the liquid epoxy 22, is attached to the substrate 16 due to the substantial differences in TCE values of the pixel array package. This is because the encapsulation material 22 in the pixel cavities is typically cured at 120° C. As the material begins to cool down to room temperature, the TCE mismatch causes the pixel array to warp upward. The amount of warping can typically be 0.005-0.010 inch per inch.

When attempting to solder the pixel array package 10 to the motherboard 24, the pixel array package being subject to a reflow temperature of 125-135 Deg C. will generally be flat with respect to the motherboard 24. However, when cooled, the pixel array package 10 will revert back to its original warped condition, thereby putting excessive stress on the solder joints. This may cause the pixel array package 10 to eventually become electrically disconnected 12′ from the motherboard 24 and ultimately cause failure of the display monitor. FIG. 1F illustrates a diagram of a pixel array warping with respect to the motherboard. As can be seen in FIG. 1F, the warping at the edges of the pixel array package can cause the connector leads to disattach from the motherboard 24 and cause the gap 35 between the adjacent packages 10 to widen. This results in a pixel array package which may not work properly and could affect the overall performance of the monitor.

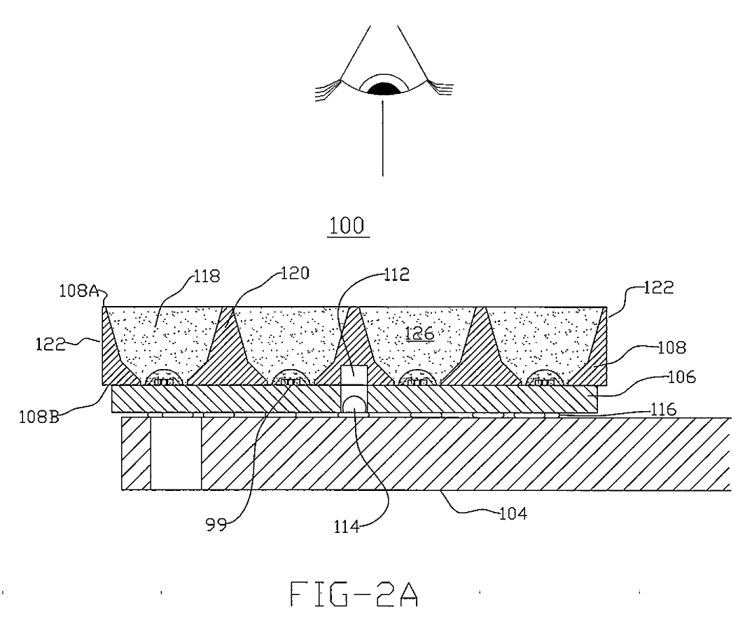

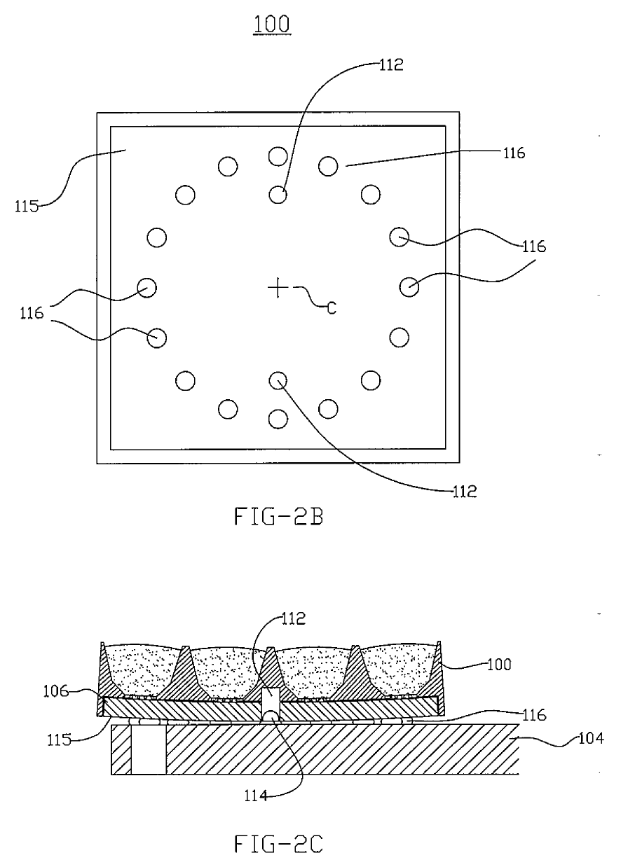

FIG. 2A illustrates a schematic of a pixel frame package mounted to a motherboard in accordance with an embodiment. As shown in FIG. 2A, the pixel frame package 100 preferably includes a molded pixel frame 108 coupled to a substrate 106. As will discussed in more detail below, the pixel frame 108 is preferably produced using a molding process in which the square pixel frame 108 is formed having four end walls 122 (two of which are shown in FIG. 2A) and a plurality of pixel walls 120 separating a plurality of cavities 118 from one another. Each cavity 118 is filled with a cavity filler material 126 such as a clear polycarbonate plastic and a diffusant, whereby the filler material 126 is preferably formed in the pixel frame 108 during a separate molding operation. In addition, within the cavities 118 are preferably housed LED units 99 which provide the illumination emitted through the cavity filler material 126 to be viewed by a user looking at the package 100 in the direction of the arrow.

FIG. 2B illustrates a bottom view of a pixel array in accordance with an embodiment. As shown in FIG. 2B, the pixel array includes a plurality of conductive leads or solder pads 116 (hereinafter referred to as “leads” or “conductive leads”) arranged in a circular or substantially circular pattern about a center point, C. The circular pattern of the leads 116 shown in FIG. 2B avoids coplanar issues resulting from warping of the pixel array package 100, as described above. In particular, the circular pattern of the conductive leads 116 allow the leads to be coplanar with one another in the event that the pixel array package warps upwards with respect to the motherboard 104 shown in FIG. 2C. As shown in FIG. 2C, the conductive leads 116 remain in contact with the motherboard 104 despite the edges of the pixel frame package 100 warping upward and away from the motherboard 104.

The arrangement of the conductive leads 116 is determined by the shape of the pixel array package 100. In the case of a square pixel array, warping at the edges will typically be symmetrical about the center of the package 100 and thus a circular pattern of leads 116 is preferred. If the pixel array is a rectangular in shape, the arrangement of the conductive leads 116 would preferably be in an elliptical pattern. It is preferred that the conductive leads 116 are configured in such a pattern that the total height between the motherboard 104 and the bottom surface 115 of the package 100 at one lead location is within 0.001 of all the other lead locations. The diameter of the circular pattern or dimensions of the elliptical pattern is preferably as large as possible to maximize the space between adjacent leads 116 so the metal traces can be placed between the leads to aid in circuit design of the motherboard.

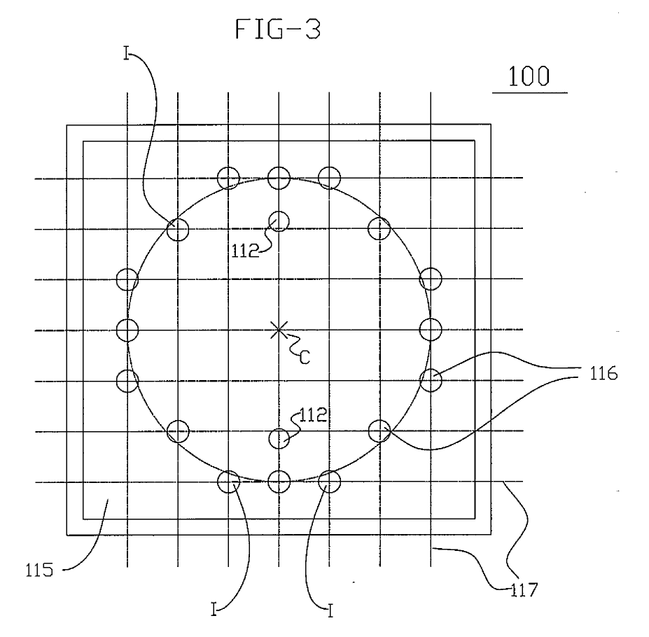

FIG. 3 illustrates a process of placing the circular pattern of solder balls or leads on the bottom surface of the pixel array, whereby a grid pattern 117 is applied to the bottom of the pixel array 100 and designated intersection locations, I, are used to place the leads 116 as indicated. As stated above, based on the overall shape of the pixel array package 100 as well as the materials of the epoxy, pixel frame and reflow process, the method determines the amount of warping that the edges of the pixel frame package will experience. This may be done by a computer software modeling program, although other appropriate methods are contemplated. Based on the predicted warping of the package, the appropriate intersection locations I where the conductive leads 116 should be placed are identified and designated. The designated intersection locations I preferably together form an overall a circular or elliptical shape along the bottom surface 115 of the package 100. Thereafter, the conductive leads 116 are placed at those designated locations I such that conductive leads 116 are arranged in the circular or elliptical shape, as shown in FIG. 3. The package 100 with a circularly or elliptically shaped conductive lead array is then preferably mounted onto the motherboard 104.

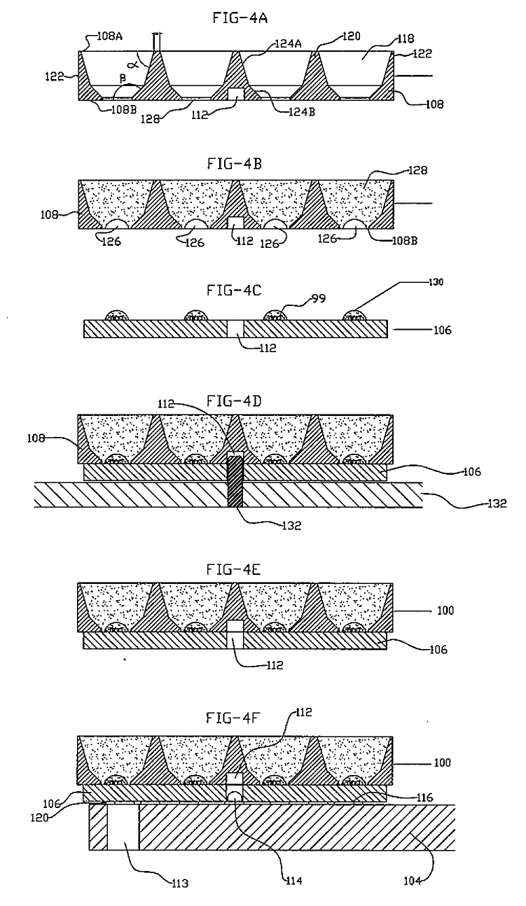

It is contemplated that alignment of more than one pixel array package 100 to the motherboard 104 is important to ensure that adjacent packages 100 abut one another to minimize the interface gap 34 (see FIG. 1D) but do not overlap one another. In an embodiment, the pixel array package 100 includes one or more alignment holes 112, whereby the alignment holes 112 serve to ensure proper placement of the pixel array package 100 on the motherboard 104 during coupling. In particular, shown in FIG. 2A, alignment balls 114 on the motherboard 104 are oriented to engage corresponding alignment holes 112 of the pixel array package 100. As shown in FIG. 2B, the bottom surface 115 of the pixel frame package 100 includes alignment holes 112 which are located to ensure alignment of the pixel array frame 108 with the substrate. In particular, as shown in FIG. 4D, an alignment pin 132 is inserted into the corresponding alignment holes 112 to align the pixel array frame 108 and substrate 106 when coupling the two to one another.

Additionally, the alignment holes 112 serve to align and maintain position of the assembled package 100 on the motherboard 104, as shown in FIG. 4F. The motherboard 104 includes one or more blind holes 113 to align the loaded motherboard onto a frame.

In particular, the alignment ball 114 on the motherboard 104 preferably forces the package 100 to automatically self align to the motherboard 104. The center to center distance between alignment balls 114 is preferably within a tolerance ±0.0005″, although other tolerance dimensions are contemplated. Since the alignment ball 114 fits within and engages the same alignment hole in the substrate 112 which is used to align with the pixel frame 108, the space 30 (FIG. 1D) is a function of how accurate the pixel frame 108 is aligned to substrate 106.

Another disadvantage with existing pixel array packages 10 is the process of forming the pixel array frame. In particular, existing methods of producing the pixel array frame 14 (FIG. 1D) include using a mold tool which makes the pixel array frames 14 in the reverse image of the pixel frame 14. The typical molding process injects heat thermoplastic into the mold. After the mold has cooled, the mold tool is opened and the pixel frame 14 part is ejected out of the mold. The molded pixel frame 14 is then attached to the substrate 16, as shown in FIG. 1D. Thereafter, encapsulation material in applied to the cavities 20 of the pixel array frame 14. The encapsulation material is typically a liquid epoxy having a viscosity around 1500 Centipoise (cps). The typical method to apply the liquid epoxy to the cavities is by using needle injection or positive displacement dispensing equipment. However, the productivity of this method is very low. Additionally, obtaining a uniform encapsulation top surface among and between the pixel cavities and along the entire pixel array using this method is extremely difficult to obtain. Further, encapsulation material may overflow into adjacent pixel cavities, which could result in light unintentionally bleeding or being transmitted between two or more pixel spaces (i.e. cross talk). It is also possible that an inadequate amount of encapsulation material may be inserted into the pixel cavities, which results in the pixel frame not adequately diffusing the LED lighting (i.e. “hot spots”). Also, the final cured surface of the encapsulation material using the conventional processes tends to produce a shiny surface whereby reflections of ambient light can adversely affect the image quality. To prevent this from occurring, additional processes such as bead blasting may be used to eliminate the shiny surface. However, such additional processes tend to produce dust and require additional control steps and therefore add expense to the manufacturing of the pixel array package.

Another disadvantage of the existing manufacturing methods for the pixel arrays relate to the size of the pixel wall gap 26 (FIG. 1D) between pixel cavities. The pixel wall gap 26 is a function of the interface gap 34 between adjacent pixel array packages 10 considering that all pixel wall gaps 26 (including interface gap 34) are preferably substantially the same width. As stated above, pixel array packages 10 placed on the motherboard 24 are separated by an expansion gap 30 prior to being attached to the motherboard 24. Additionally, after the pixel array packages 10 are attached to the motherboard 24, the gap between the pixel array packages, as termed above the interface gap 34, can be significantly large, as shown in FIG. 1D. This results in an increased viewing distance required for the display monitor. The above mentioned existing methods of manufacturing the pixel array package and attaching it to the motherboard can have an adverse affect on the size of the interface gap 34 as well as the wall gaps 24 and it is already at it limits of manufacturing in reducing the gap between pixels under existing manufacturing methods.

The size of the interface gap 34 depends on a variety of factors, some of which are based on dimensions and materials of the pixel array packages 10 as well as the expansion gap 30. In particular, a registration and/or location tolerance dimension 32 on each end of the pixel array package 10 as well as the dimensions of the end walls 38 dictate the size dimension of the interface gap 34 since all the pixel wall gaps 26 (including the interface gap 34) are to be substantially the same size.

In addition, the pixel array package 10 undergoes thermal expansion during manufacturing which may add to the size of the interface gap 34. In particular, heat is applied during a soldering reflow step in attaching the pixel array package 10 to the motherboard 24. Based on the type of solder used, the reflow temperature must be higher than the melting point of the solder to ensure that the solder sufficiently melts to create the desired metallurgical bond. However, the heat applied to the pixel array package 10 and motherboard 24 may cause the pixel array frame 14 and/or encapsulation material to expand due to their respective TCE rates. Considering several pixel array packages 10 may be attached adjacent to one another on the motherboard 24, space between adjacent pixel array packages must be taken into account to ensure that the packages abut one another completely and also do not overlap.

FIGS. 4A-4D illustrate a manufacturing process in producing a pixel array package which overcomes the problems stated above. As shown in FIG. 4A, the pixel frame 108 is produced using a molding process in which the pixel frame 108 is formed having two end walls 122 and a plurality of pixel walls 120 separating a plurality of pixel cavities 118. The end walls 122 are preferably one half the width of the full pixel walls 120, as measured at the top surface 108A of the pixel frame 100, along with the difference of one half of the expansion gap 30.

In the embodiment in FIGS. 4A-4D, the pixel walls 120 have a upper portion 124A and a lower portion 124B, whereby the upper portion is angled at an angle, α, with respect to the top surface 108A of the frame 108. The bottom portion 124B of the pixel wall 120 is oriented at an angle β with respect to the bottom surface 108B of the pixel array 108. In the embodiment shown in FIG. 4A angle α is greater than angle β. In the embodiment shown in FIG. 4A angle α is lesser than or equal to angle β. The dimensions and design of the pixel walls 120 may depend on the material used in the pixel array 108 as well as the desired amount of light emitted from the pixel array package 100. Although the pixel walls 120 have the configuration shown in FIGS. 4A-4D, other pixel wall configurations are contemplated.

In addition, as shown in FIG. 4B, the pixel array frame 108 undergoes a second molding process to apply a cavity filler material 128 such as a clear polycarbonate plastic and a diffusant to the pixel cavities 118. Other materials that could be used are acrylic or other thermoplastics that are resistant to discoloring (yellowing) at elevated temperature and UV exposure. Polycarbonate has higher heat resistant (140 Deg C.) compared to acrylic (110 Deg C.). In an embodiment, the cavity material 128 is applied during the second molding step (the first being molding the pixel array frame).

By applying the cavity filler material 128 to the pixel array frame 108 using a molding process, the cavity filler material 128 fills the cavities 118 and forms a uniform surface along the top surface 108A of the pixel array frame 108, as shown in FIG. 4B. Such uniformity of the cavity material 128 allows the pixel package 100 to have a substantially constant height and eliminates hot spots or cross talk among pixel cavities. Additionally, considering that the cavity material 128 is applied in a molding process, the optical surface finishing of the material 128 can be controlled by selecting the surface finish. In particular the surface finish can be specified to produce consistent optical finishes among the pixel arrays.

In an embodiment, the pixel frame 108 is made from a highly filled thermoset plastic-like material such as an electronic mold compound. Considering that the mold compound is a thermoset, it does not typically re-melt at standard solder reflow temperatures. Pixel frame 108 is preferably made from a highly filled mold compound, with filler content of 75-85% by volume, could be attached to the substrate 106. The TCE of the pixel frame 108 made from this material would preferably match the substrate 106. Thus, when the epoxy diffusant 128 is dispensed and cured, the combination of the substrate and high filled thermoset pixel frame 108 would provide the additional stiffness to reduce warping.

As shown in FIG. 4B, the molded pixel array frame 108 is formed to include light pits 126 along the bottom surface 108B, whereby the light pits 126 serve to house the LEDs 99 once the frame 108 is attached to the substrate 106 (FIG. 4C). In an embodiment, the light pits 126 are formed during the process in which the cavity material 128 is applied (FIG. 4B), whereby pins (not shown) are inserted into the apertures 128 on the bottom surface via the bottom surface 108B of the frame 108. Preferably, the protrusions remain within the cavity while the cavity filler material is applied. Once the material is applied and hardened, the domed protrusions are removed from frame 108 to form the light pits 126. It should also be noted that although the light pits 126 are described as being formed during the molding process in the pixel array frame 108, the light pits 126 may be formed using any other appropriate methods, such as machining, or during a process other than the cavity filler molding process.

In FIG. 4C, LEDs 99 which are mechanically coupled to the substrate 106 have flexible adhesive 130 applied thereon. The flexible adhesive 130 protects the LED 99 during manufacturing and also ensures a strong mounting with the cavity filler material 128 above the light pits 126. Silicone or aliphatic polyurethane are some preferred adhesives, although any appropriate type of adhesive is contemplated. Thereafter, the pixel array frame 108 is brought into contact with the substrate 106, whereby the LEDs 99 are inserted into the hollow light pits 126, as shown in FIG. 4D. As discussed above, an alignment pin 132 preferably protruding from a pin alignment plate tool 132 is inserted into the alignment holes 112 in the pixel array frame 108 and the substrate 106 to align the two. The pre-molded pixel array frame 108 is then effectively attached to the substrate 106 such that the LEDs 99 are “optically” coupled to the pixel array frame 108. Additionally, the LEDs 99 are “mechanically” decoupled from the substrate 106. This is due to the pre-molded pixel array frame 108 and above described manufacturing methods allow the materials of the pixel array frame 108 and substrate 106, both having very different TCE coefficients, to expand freely with respect to one another during manufacturing or operation without sacrificing or compromising the structure of the pixel array package 100.

In an embodiment, the materials of the pixel array package 100 allow it to be attached to the motherboard 104 using conventional solder rather than a low temperature solder. This translates into a significant cost reduction as well as reduction in the size of the interface gap 34. In particular, low temperature solder contains approximately 48% indium (In) and 52% Tin (Sn), whereby the low temperature solder can cost approximately $6.00 per gram. In contrast, conventional solder having a mixture 96% Sn and 3.5% silver (Ag) can cost around $0.50 per gram. The thermoplastic used to make the pixel array frame 108 can not be used with conventional soldering processes since the frame 108 will be subject to the intense heating required in soldering. Substrate 106 with LED 99 (FIG. 4C) can be solder to motherboard 104 prior to attaching the pre-formed pixel frame (FIG. 4B). This would allow the use of conventional solder alloys. Thus, use of the pre-formed pixel array frame 108 can result in significant cost savings.

Another advantage of the pre-molded pixel frame array 108 is that it does not have to be exposed to solder reflow temperatures. The thermal expansion gap 30 which is required between adjacent pixel packages is determined by 1) the curing temperature of the flexible adhesive that optically couples the LED 99 to the pixel frame array 108 (which can be at room temperature) and/or 2) the operating temperature of the pixel array package 100. Assuming that the display monitor which houses the plurality of pixel array packages 100 operates in a 30 Deg C. environment and generates about 30 Deg C. in operating heat, the TCE rate of the polycarbonate material of the package 100 would be 70 PPM/Deg C. This allows in the expansion gap 30 to be reduced from 0.006″ to 0.003″. For a 1″ pixel array, the interface gap 34 would be reduced from 0.018″ to 0.015″. For a 0.5″ inch size pixel array, the interface gap 34 would be reduced from 0.015″ to 0.0135″. This reduction results in an overall reduction in the interface gap 34 between adjacent pixel packages 100. As mentioned above, the pixel wall gaps 26 have the same width as the interface gap 34. Therefore, a reduction in the interface gap 34 will result in a reduction of the width of the pixel wall gaps 26. As a result, more pixel array packages 100 are able to fit into the display monitor. Alternatively, the reduction would result in individual pixels being smaller, thereby reducing the viewing distance.

In an embodiment, a low temperature curable attachment material 102 is used to attach the pixel array package 100 to the motherboard 104, whereby the use of the low temperature attachment material can reduce the interface gap 34 between adjacent pixel array packages 100. An example an appropriate low temperature cure is a silver filled epoxy. Silver filled epoxy can be cured around 100 Deg C. or less, which is substantially lower than the low temperature solder discussed above. The less heat that is needed to ensure attachment of the pixel array packages 100 to the motherboard 104 will reduce the amount of thermal expansion that the pixel array package 100 experiences during the attachment process to the motherboard 104. In an example, replacing low temperature solder with silver filled epoxy in attaching the pixel array package 100 to the motherboard 104 reduces the size of the expansion gap 30 from 0.006″ to 0.0004″ for 1″ pixel array packages 100. By using the silver filled epoxy, the pixel array package 100 thus does not require being exposed to solder reflow temperatures which also reduces the size of the interface gap 34.

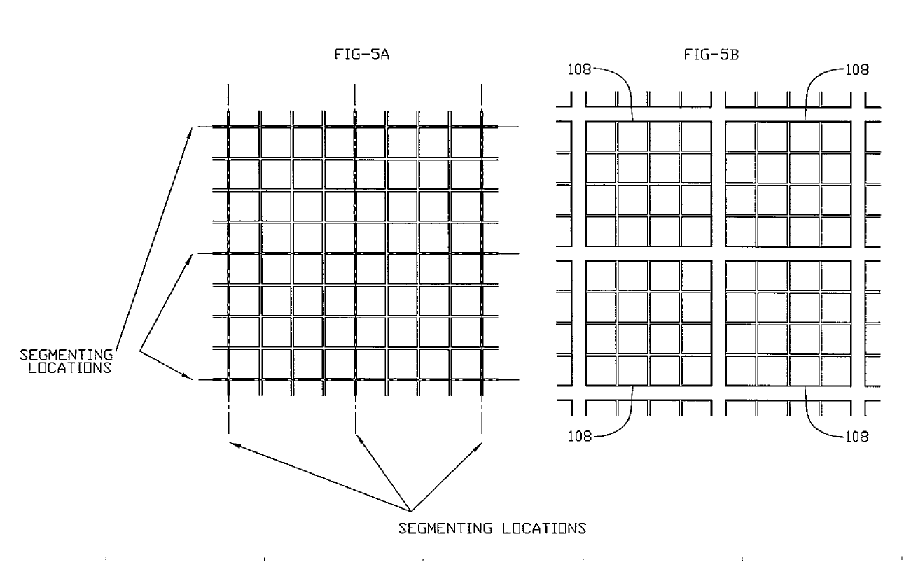

In an embodiment, the preformed pixel array frame 108 can be produced in larger panels as in FIGS. 5A and 5B and are segmented to a desired size for a pixel array. Such methods of segmenting includes but is not limited to sawing, high pressure (water) jets, (laser) etc. In an embodiment, the segmenting process removes material such as a portion of the end walls 122 of the pixel array frame 108 to separate adjacent pixel frames apart from one another as shown in FIG. 5B. Based on the method of segmenting used, the wall thickness of the pixel array frame 108 could be reduced from 0.004″ to 0.002″. As a result, the pixel gap 26 for 1″ size pixel array can be reduced to 0.011″. For a 0.5″ pixel array, the pixel gap 26 can be reduced to 0.0095″. As discussed herein the reduction of the wall thickness of the pixel array frame 108 leads to the reduction in the pixel size and thus a reduction in the overall size of the pixel array considering that the uniformity of the pixels require that all the pixel walls, between neighboring pixel cavities, have the same width dimension at their top surface (reference numeral 111 in FIG. 4A). This reduction thus results in an increase in the pixel array frames 108 which can be placed within a given area. This results in higher resolution.

As stated above, a low temperature silver epoxy can be used to join the pixel array and substrate array to the motherboard, whereby the use of silver epoxy will reduce the expansion gap 30 (FIG. 1D) between adjacent pixel arrays. In the embodiment where silver epoxy is used on previously segmented pixel arrays, the combination of the two processes can even further reduce the interface gap 34 between the pixel array packages 100. For example, using silver epoxy for a 1″ pixel array would require an interface gap of approximately 0.012″. However, unlike soldering, epoxies do not serve to “self align” the pixel array package 100 with the motherboard 104 during the mounting process.

Although use of silver epoxy has its advantages, it may be preferable to use solder to mount the package 100 to the motherboard 104. In using solder, the surface tension between the solder balls on the motherboard 104 and the substrate 106 allows the package 100 to center itself on the motherboard 104. The self centering of the substrate 106 on the motherboard 104 prevents adjacent packages 100 from mechanically interfering with one another. Accordingly, in an embodiment, solder balls 102 are pre-attached to the bottom surface of the pixel array package 100, whereby the solder balls 102 act as alignment members in mounting the package 100 to the motherboard 104. In particular, the alignment balls 114 disposed on the substrate 104 fit into the designed pixel array alignment holes 112, as shown in FIG. 4E. Thus, the location accuracy for pixel array package 100 is the difference between alignment hole 112 size and alignment ball 114 size. For example, if the hole size is 0.032″ and ball size is 0.030″, the location accuracy is ±0.001″.

The solder balls 102 are preferably made from conventional solder such as Sn/Pb, or Sn/Pb/Ag alloys, although other materials or combination of materials are contemplated. In an embodiment, the solder balls 102 are then reflowed to the metal pad on the motherboard 104 to electrically connect the pixel array package 100 is to the motherboard 104. It is possible to design the alignment hole 114 and alignment ball 112 size such that the pixel array package is able to be mounted to the motherboard 104 using a light press fit. It is contemplated that conductive epoxy or any other mounting technology other that solder is applicable while using the alignment mechanism of the present embodiment.

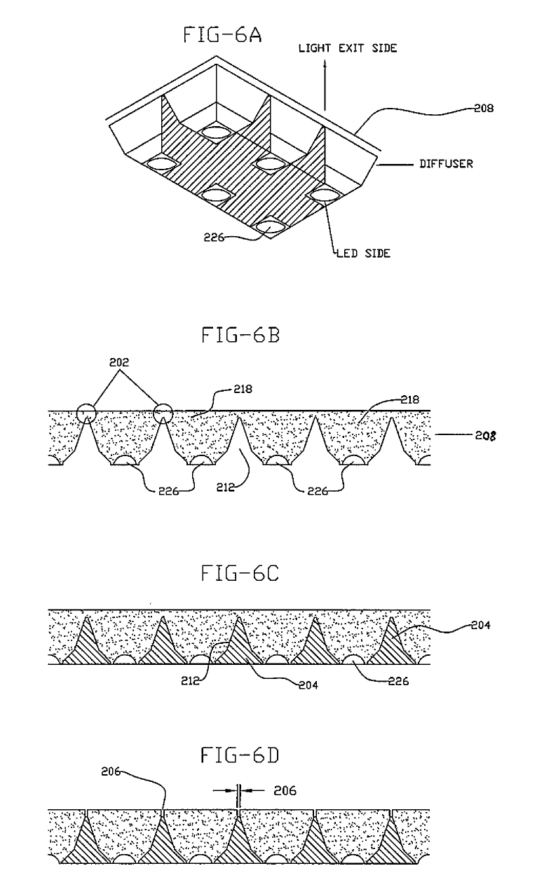

FIG. 6A illustrates a perspective view of a pixel array frame 208 in accordance with an embodiment. FIGS. 6B-6D illustrate a process of producing the pixel array frame 208 in accordance with an embodiment. As shown in FIG. 6B, the pixel array frame 208 is formed preferably by a molding process, whereby polycarbonate material is used as a diffusant material to form the pixel array frame 208. In particular, as shown in FIG. 6B, the pixel array frame 208 is formed to produce a series of filled pixel cavities 218 which are mechanically connected to one another via array bridges 202. In addition, during the molding process (or in a different step) as shown in FIG. 6B, light pits 226 are created for the insertion of LEDs 99 in each pixel cavity 218.

Thereafter, as shown in FIG. 6C, the molded pixel array frame 208 is preferably subjected to a second molding process, whereby reflective material 204 is inserted into the pixel wall cavities 212 to form the pixel walls 212. It is preferred that the reflective material 204 is a white polycarbonate, although other appropriate materials are contemplated including, but not limited to liquid epoxy filled titanium oxide. The process ensures that reflective material 204 is prevented from entering the light pits 226 during this step or cross-talk between pixels 218. In an embodiment, the light pits 226 may be formed in the pixel array frame 208 after the reflective material 204 is inserted into the pixel wall cavities 212. After molding, an annealing step may be performed to reduce the internal stress with the pixel array frame 108 to achieve a frame 208 that is dimensionally stable during processing.

Once the molded materials have hardened, it is preferred that the pixel array frame 208 is partially segmented 206 at the pixel walls 204 to cut through the diffusant material 218, as shown in FIG. 6D. The segmentations 206 are positioned at the pixel walls 204 such that the breaks in the diffusant material eliminate cross talk of light between the individual cavities 218. An advantage of forming the pixel array frame 208 using the method is that the expansion gap 30 is no longer a considered factor during the manufacturing process. This is so because the pixel array frame 208 is initially formed with the diffusant material therein and the pixel walls are subsequently formed, and no change occurs in the dimensions during these processes. For example, for a 1″ pixel array, the interface gap 34 can be reduced to 0.007″. For a 0.5″ pixel array, the interface gap 34 using the above method can be reduced to 0.0055″. It should be noted that the above embodiment in FIGS. 6A-6D can incorporate some or all of the inventive features described above with respect to the other disclosed embodiments.

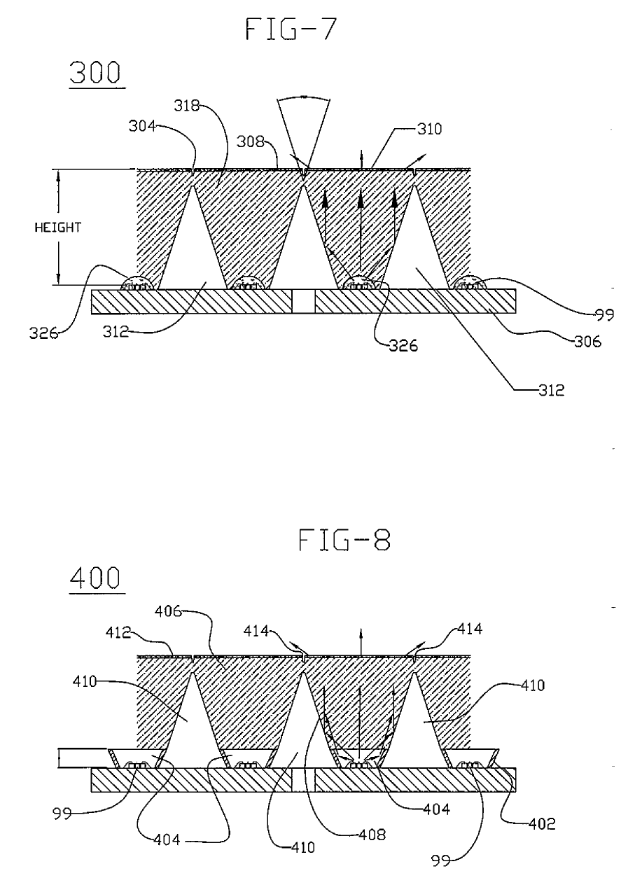

FIG. 7 illustrates a pixel array package 300 in accordance with an embodiment. As shown in FIG. 7, the pixel array package 300 includes alternating pixel cavities 318 and pixel walls 312. Light pits 326 within the pixel cavities 318 house the individual LEDs 99, whereby the pixel walls 312 prevent cross talk of light between adjacent pixel cavities 318. As described above in FIG. 6D, segmentations 304 may be incorporated through the top surface 308 and into the diffusant material to further prevent cross talk of light between cavities 318. Along the top surface of the pixel array package 300 is a light diffusing layer 310 preferably made of low temperature curing liquid epoxy with diffusant material within the liquid epoxy, whereby the light diffusing layer 310 serves to scatter the light emitted from the LEDs 99 a maximum viewing angle, as shown by the arrows in FIG. 7. It is contemplated that the light diffusing layer 310 can be made of any other appropriate material. The light diffusing layer 310 is preferably applied to the pixel array package 300 using a printing technique, although other appropriate techniques are contemplated in applying the light diffusing layer 310. For example, the molding tool could have a pattern on the mold tool surface so that the molded part is created with the pattern embedded on the surface shown as diffusing layer 310. Although the light diffusing layer 310 is shown in the embodiment in FIG. 7, the layer 310 is applicable to any or all of the described embodiments herein.

As shown in FIG. 7, the pixel walls 312 do not include reflective material therein as described in FIG. 6C, but instead house a gas, including, but not limited to, air. The pixel array package 300 in the embodiment in FIG. 7 acts to bend light emitted from the LEDs 99 due to the density change in material between the gas filled pixel walls 312 and the diffusant filled pixel cavities 318. For example, the index of refraction for a clear polycarbonate material which contains no diffusant is approximately 1.52 whereas the index of refraction for air is approximately 1.00. The difference in the index of refraction between the two materials in the pixel array package 300 causes the light from the LEDs 99 to reflect upward toward the top surface 308 as the light strikes the air-filled pixel walls 312, as discussed in more detail below.

Total internal reflection occurs when a ray of light strikes a medium boundary at an angle larger than the critical angle with respect to the normal to the surface. If the refractive index is lower on the other side of the boundary then no light can pass through, thereby effectively reflecting all of incident the light. The critical angle is the angle of incidence above which the total internal reflection occurs. When light crosses a boundary between materials with different refractive indices, the light beam will be partially refracted at the boundary surface and partially reflected. However, if the angle of incidence is greater (i.e. the ray is closer to being parallel to the boundary) than the critical angle, then the light will stop crossing the boundary altogether and instead be totally reflected back internally. This can only occur where light travels from a medium with a higher refractive index to one with a lower refractive index, such as when light passes from glass to air, although not when light passes from air to glass.

The critical angle is the angle of incidence above which total internal reflection occurs. The angle of incidence is measured with respect to the normal at the refractive boundary. The critical angle θ_{c} is given by equation (1):

$${Θ}_{c} = arcsin ( \frac{{n}_{2}}{{n}_{1}} ) \qquad ( 1 )$$

where n₂ is the refractive index of the less dense medium, and n₁ is the refractive index of the denser medium. This equation is an application of Snell's law where the angle of refraction is 90°. If the incident ray is precisely at the critical angle, the refracted ray is tangent to the boundary at the point of incidence.

As the reflected light travels through the pixel cavities 318, which are made of a clear, non-diffusing material the light diffuses outward, as shown by the arrows to provide a maximum dispersion of light from the pixel array package 300. An advantage of the pixel array package 300 in FIG. 7 is that it simplifies manufacturing of the pre-molded pixel array frame, considering that the pixel array frame may be produced by only one molding operation before being attached to the substrate 306. It should be noted that although air is disclosed as the preferred gas within the pixel walls 312, any other type of gas with appropriate density characteristics may be used within the pixel walls 312 (The surface smoothness along reflecting walls is define typically as 10% of the wavelength.)

FIG. 8 illustrates a schematic of a pixel array package 400 in accordance with an embodiment. As described above, if the angle of the light is less than the critical angle, some it will not be reflected. Since light emitted from the LED 99 is semi-spherical, some light will be lost. FIG. 8 shows an added feature to help capture this lost light. In this case, the reflection method can be “total internal reflection plus specular reflection” or “total internal reflection plus diffused reflection.” As shown in FIG. 8, the pixel array package 400 contains similar features and design as the pixel frame in FIG. 7 with the exception of low profile reflector elements 402 positioned proximal to the LED light pits 404. The reflector elements 402 in FIG. 8 preferably line the inside walls of the pixel cavities 406 and extend upwards from the light pit 404 a distance to ensure that light emitted from the LEDs 99 which strikes the walls 408 of the pixel cavities do not traverse into the gas-filled pixel walls 410 and thereby escape from the pixel array frame 400. Light which is subject to passing through the pixel wall cavities 406 thus will reflect off of the low profile reflectors 402 and be redirected back toward the non-diffusant material in the pixel cavity 406 and upwards toward the top surface 412. For a specular reflection, reflector elements 402 may be made from stamped metal having a reflective surface and plated with nickel to direct the light upward, although other appropriate materials are contemplated. For a diffused reflection, reflector elements 402 may be white material like white polycarbonate thermoplastic. The height H of the reflector elements 402 is based on the intensity and propagation frequency of the light emitted from the LEDs as well as the angle of the walls 408 of the pixel cavities 406. The shape of the pixel walls 406, height of reflective elements 402, and types of gas may be modeled using modeling software before any tooling is performed. It should be noted that the pixel walls are shown in FIGS. 7 and 8 to be triangular in cross-section for example purposes, and other cross sectional designs of the pixel walls are contemplated. For example, the pixel walls in FIGS. 7 and 8 may have a shape substantially similar to the shape of the pixel walls in FIG. 6C. As with the embodiment in FIG. 6C, the package in FIG. 8 also preferably includes one or more segmentations 414 on its top surface 412.

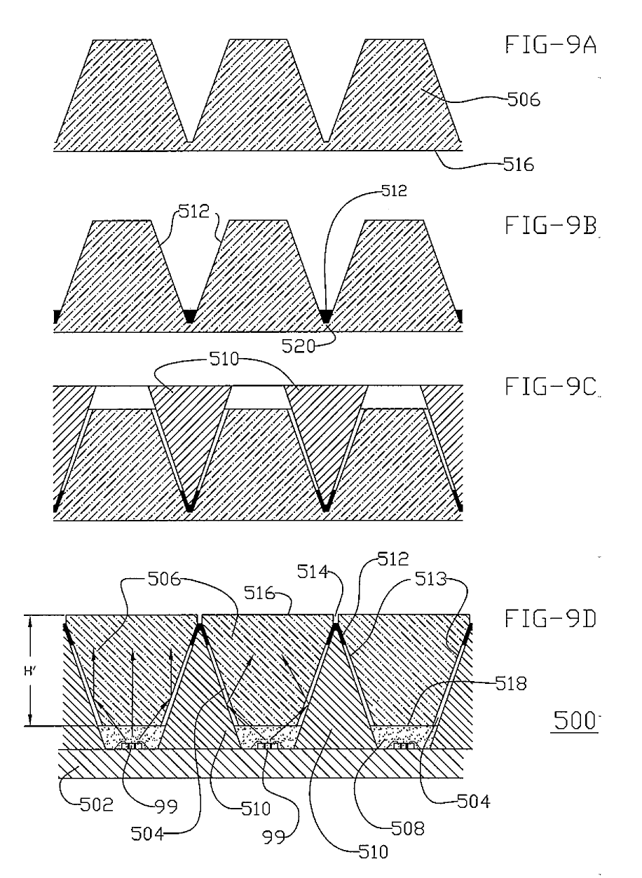

FIGS. 9A-9D illustrate a package in accordance with an embodiment that substantially eliminates light cross talk between pixel cavities. FIG. 9D illustrates the package 500 which includes a substrate 502 having LEDs 99 positioned within low profile reflector elements 508. In addition, the package 500 includes a plurality of triangular shaped pixel walls 510 adjacent to the reflector elements 508, whereby pixel cavities 506 are located above the reflector elements 508 and next to the pixel walls 510. The pixel cavities 506 have similarly angled sides 513 and a height dimension H′ such that a bottom section 518 rests upon the reflector elements 508. The top surface 516 of the cavities 506 form the light emitting surface of the pixel array package 500. The widths and similarly angled sides of the pixel cavities 506 and pixel walls 510 allows formation of a gas filled gaps 504 between the pixel walls 510 and the pixel cavities 506 as shown in FIG. 9D. The gas in the gaps 504 is preferably air, although any other appropriate gas is contemplated. It should be noted that although the gaps 504 are shown to be uniform along their length, non-uniform gaps 504 are contemplated as well. As shown in FIG. 9D, the an adhesive material 512 having light blocking properties is present near the top surface 516 to prevent light from escaping through the gaps 513. Additionally, segmentations 514 in the top surface prevent cross-talk or bleeding of light from adjacent pixel cavities.

The configuration of the pixel package 500 is such that the pixel walls 510 catch and redirect any light emitted from the LED 99 that is less than the critical angle while the walls 513 reflect light greater than the critical angle. The combination of “diffused” reflection plus total “total internal” reflection results in brighter and more efficient use of light emitted from the LEDs 99.

Another advantage of the embodiment in FIG. 9D is that the pixels will tend to look darker when the LEDs 99 are not operating, thereby providing a greater contrast ratio between operating and non-operating pixels. In particular, ambient light entering through the top surface of the pixel frame may illuminate the entire pixel frame. The embodiment, ambient light entering a pixel will be parallel, whereby the shape and smoothness of the pixel walls 510 and cavities 506 as well as the areas of the pixel gaps 513 will direct the ambient light to converge on the LED. This results in total internal reflection of the ambient light in the pixel cavity, whereby the ambient light will not illuminate the walls of 510. This results in a darker looking pixel package when the LED 99 is not emitting light.

FIGS. 9A-9D illustrate a method of manufacturing the pixel package 500 discussed above. As shown in FIG. 9A, the frame which serves as the pixel cavity 506 is preferably formed by a molding process. The pixel cavity 506 is shown in FIG. 9A as being upside down, whereby surface 516 serves as the top surface of the pixel package in FIG. 9D. Thereafter, as shown in FIG. 9B, adhesive 512 is applied to the valleys 520 where the sides 512 of the pixel cavities 506 converge. Thereafter, the pixel walls 510, which are preferably formed separately by a molding process are mounted to the pixel cavity frame 506 such that the tips of the pixel walls 510 are attached to the valleys 520 via the adhesive 512. LED 99 and substrate 502 are attached after completion of FIG. 9C. Once the LED/Substrate is attached, the partial segmenting 514 and full segment preferably occur at the same time to form the pixel array package.

While embodiments and applications have been shown and described, it would be apparent to those skilled in the art having the benefit of this disclosure that many more modifications than mentioned above are possible without departing from the inventive concepts disclosed herein. The invention, therefore, is not to be restricted except in the spirit of the appended claims.

What is claimed is:

1. A method of manufacturing a display monitor, the method comprising:
molding a pixel array frame having a top surface and a bottom surface, the pixel array frame having a plurality of pixel cavities and at least one pixel wall positioned adjacent to at least two pixel cavities, at least one of the pixel cavities having a light pit proximal to the bottom surface; and
molding a light diffusing material in the pixel cavities, wherein the light diffusing material does not enter the light pit.

2. The method of claim 1 further comprising selecting a substrate having a top surface and a bottom surface, the substrate having a light source on the top surface.

3. The method of claim 2 further comprising:
coupling the bottom surface of the substrate to a printed circuit board configured to controllably operate the light source; and
coupling the molded pixel array frame to the substrate wherein the light source is received within the light pit.

4. The method of claim 1 wherein the pixel frame array is made of a polycarbonate material.

5. The method of claim 2 further comprising coupling a plurality of conductive leads adapted to the bottom surface of the substrate in a substantially circular pattern with respect to a center point.

6. The method of claim 1 further comprising forming an alignment hole in the bottom surface of the pixel array frame, wherein the alignment hole is configured to align the pixel array frame to a substrate having a light source thereon.

7. The method of claim 2 further comprising forming an alignment hole in the bottom surface of the pixel array frame, wherein the alignment hole is configured to align the pixel array frame to the top surface of the substrate.

8. The method of claim 3 wherein the bottom surface of the substrate has an alignment hole formed therein, wherein the alignment hole is configured to receive a alignment member of the printed circuit board therein to align the substrate to the printed circuit board.

9. A pixel array package comprising:
a pixel array frame having a plurality of pixel cavities and at least one pixel wall positioned adjacent to at least two pixel cavities, at least one of the pixel cavities having a light pit therein, the molded pixel array frame having a light diffusing material in the pixel cavities;
a substrate having a top surface and a bottom surface, the substrate having a light source on the top surface, wherein the top surface of the substrate is coupled to a bottom surface of the pixel array frame, wherein the light source fits within the light pit;
a plurality of conductive leads adapted to couple the substrate to a printed circuit board, the conductive leads coupled to the bottom surface of the substrate in a substantially circular pattern with respect to a center point.

10. The package of claim 9 further comprising an alignment hole in the bottom surface of the substrate, wherein the alignment hole is adapted to receive a corresponding alignment member from a printed circuit board when the substrate is coupled to the printed circuit board.

11. The package of claim 9 wherein the pixel walls are filled with a gas.

12. The package of claim 9 wherein the pixel walls are filled with a reflective material.

13. The package of claim 9 further comprising a reflective element on an interior surface of the pixel cavities proximal to the light pit, wherein the reflective element extends upward a desired distance from the bottom surface of the pixel array frame.

14. The package of claim 9 further comprising an alignment hole in the bottom surface of the pixel array frame, wherein the alignment hole is configured to align the pixel array frame to the top surface of the substrate.

15. The package of claim 9 further comprising a light diffusing layer material on the top surface of the pixel array frame.

16. A method of manufacturing a pixel array package comprising:
molding a pixel array frame having a top surface and a bottom surface separated by a first height dimension, the pixel array frame having a plurality of pixel cavities having of a light diffusing material formed therein and separated by pixel walls having a space devoid of material, wherein each pixel cavity includes a light pit proximal to the bottom surface, the light pit being free of the light diffusing material, each pixel cavity separated by a bridged area of light diffusing material proximal to the top surface and positioned above the pixel walls wherein the bridged area of light diffusing material has a second height dimension less than the first height dimension;
removing a segment of the light diffusing material at the bridged area, wherein the removed segment extends from the top surface down a third height dimension toward the bottom surface, the removed segment configured to prevent light from a first pixel cavity from diffusing into an adjacent second pixel cavity.

17. The method of claim 16 further comprising applying a reflective material within the space of the pixel walls.

18. The method of claim 16 wherein the segment has a width dimension substantially equal to a width dimension of the pixel wall.

19. The method of claim 16 wherein the third dimension is less than the second dimension.

20. The method of claim 17 wherein the third dimension is substantially equal to the second dimension.

21. The method of claim 16 further comprising applying a reflective element on an interior surface of the pixel cavity proximal to the light pit, wherein the reflective element extends upward from the bottom surface of the pixel array frame a desired distance.

22. The method of claim 16 further comprising applying a light diffusing layer material on the top surface of the pixel array frame.

23. A method of manufacturing a display monitor, the method comprising:
molding a pixel array frame having a plurality of pixel cavities and at least one pixel wall positioned adjacent to at least two pixel cavities, at least one of the pixel cavities having a light pit therein;
molding a light diffusing material in the pixel cavities, wherein the light diffusing material does not enter the light pit;
selecting a substrate having a top surface and a bottom surface, the substrate having a light source on the top surface;
coupling the bottom surface of the substrate to a printed circuit board configured to controllably operate the light source, wherein the light source is received within the light pit; and
coupling the molded pixel array frame to the substrate.
